(19) United States
(12) Patent Application Publication
(10) Pub. No.: US 2010/0101630 A1
(43) Pub. Date: Apr. 29, 2010

(54) Terrestrial Solar Tracking Photovoltaic Array with Slew Speed Reducer

(75) Inventors: Mikhail Kats, Rockaway, NJ (US); Gary Hering, Belle Mead, NJ (US); Peter Allen Zawadzki, Clinton, NJ (US); James Sheman, Hillsborough, NJ (US)

Correspondence Address: EMCORE CORPORATION, 1600 EUBANK BLVD, S.E., ALBUQUERQUE, NM, 87123, US

(73) Assignee: Emcore Solar Power, Inc., Albuquerque, NM (US)

(21) Appl. No.: 12/574,508

(22) Filed: Oct. 6, 2009

Related U.S. Application Data
(63) Continuation-in-part of application No. 12/478,567, filed on Jun. 4, 2009.
Application No. 12/478,567 is a continuation-in-part of application No. 12/257,670, filed on Oct. 24, 2008.

(51) Int. Cl. H01L 31/052

(52) U.S. Cl. 136/246

(57) ABSTRACT

A terrestrial solar tracking photovoltaic array with a longitudinal support that may be constructed of discrete sections. The overall length of the array may be adjusted depending upon the necessary size of the array. A drive may be configured to rotate the longitudinal support about a first axis. The drive may include a slew speed reducer. Solar cell modules are positioned along the longitudinal support and may each include a rectangular case with a plurality of lenses that are positioned over corresponding receivers. Linkages may be connected to frames and are axially movable along the longitudinal support to rotate the solar cell modules within second planes that are each orthogonal to the first plane to further track the sun during the course of the day.

### RELATED APPLICATION

The present application is a continuation-in-part of U.S. patent application Ser. No. 12/478,567 filed Jun. 4, 2009 which itself is a continuation-in-part of U.S. patent application Ser. No. 12/257,670 filed Oct. 24, 2008. Each of these references is herein incorporated by reference in their entirety.

### BACKGROUND

The present application is directed to a terrestrial solar tracking photovoltaic array and, more particularly, to a modular array with solar cell modules that are simultaneously movable about first and second orthogonal axes to maintain the solar cell modules aligned with the sun.

Terrestrial solar tracking photovoltaic arrays are used for various applications. The arrays are designed for a specific output capacity and cannot be modified in a convenient manner for different capacities. The set capacity of the arrays may vary from being relatively small, such as a few kilowatts, to relatively large in excess of hundreds of kilowatts. The arrays may be installed at various locations that have exposure to the sun for adequate periods of time to produce the required power capacity.

The photovoltaic arrays generally include a frame with one or more solar cell modules in the form of panels. The frame may be adjustable to position the solar cell modules towards the sun. The frame may adjust the position of the solar cell modules throughout the day to ensure they remain directed to the sun to maximize the power capacity.

Many existing photovoltaic arrays include large frames that support the solar cell modules. The size of the frames and installation requirements often result in their costs being substantial. Initially, the frames are moved by large trucks or other like equipment to the installation site. Cranes or other like lifting equipment are necessary to lift the frames from the trucks and position them at the correct location. This installation process often requires a large workforce due to the extensive moving and assembly requirements of mounting the frame and attaching the associated solar cell modules. These prior designs did not allow for a single person or just a few persons to install the frame and solar cell modules.

These prior frames also provide for mounting a predetermined number of solar cell modules. There was no ability to modify the number of solar cell modules to accommodate the specific needs of the array. Particularly, there is no manner of modifying the design out in the field during or after the installation.

### SUMMARY

The present application is directed to a terrestrial solar tracking photovoltaic array. The array may include a modular design that is sized and weighted to facilitate installation with a small amount of manpower. The array further is adapted to be adjusted during or after installation to accommodate the necessary power requirements.

The terrestrial solar tracking photovoltaic array includes a longitudinal support that may be constructed of discrete sections. The overall length of the array may be adjusted depending upon the necessary size of the array. A drive may be configured to rotate the longitudinal support in first and second directions about a first axis. The drive may include a slew speed reducer. The slew speed reducer may include embedded first and second members and a gear. Solar cell modules are positioned along the longitudinal support and may each include a case with a plurality of lenses that are positioned over corresponding receivers. The receivers may include III-V compound semiconductor solar cells. Linkages may be connected to frames and may be axially movable along the longitudinal support to rotate the solar cell modules within second planes that are each orthogonal to the first plane to further track the sun during the course of the day.

The various aspects of the various embodiments may be used alone or in any combination, as is desired.

### BRIEF DESCRIPTION OF THE DRAWINGS

FIG. 1 is a perspective view of a terrestrial solar tracking photovoltaic array according to one embodiment.

FIG. 2 is a perspective view of a mount and solar cell modules connected to a longitudinal support according to one embodiment.

FIG. 3 is a perspective view of a mount connected to a longitudinal support according to one embodiment.

FIG. 4 is a perspective view of a pair of mounts connected to a longitudinal support according to one embodiment.

FIG. 5 is a perspective view of mounts and solar cell modules connected to a longitudinal support according to one embodiment.

FIG. 6 is a perspective view of a base connected to a longitudinal support according to one embodiment.

FIG. 7 is a partial perspective view of a linkage and a pivot coupling according to one embodiment.

FIG. 8 is a perspective view of a coupling connected to linkages according to one embodiment.

FIG. 9 is a partial perspective view of a mount connected to a longitudinal support and a drive operatively connected to the longitudinal support according to one embodiment.

FIG. 10 is a top view of a portion of a terrestrial solar tracking photovoltaic array according to one embodiment.

FIG. 11 is a schematic side view of an anti-backlash mechanism extending outward from a longitudinal support according to one embodiment.

FIG. 12 is a partial schematic view of a biasing member operatively connected to the longitudinal support according to one embodiment.

FIG. 13 is a schematic end view of a balancing mechanism operatively connected to a terrestrial solar tracking photovoltaic array according to one embodiment.

FIG. 14A is a schematic side view of gears of a drive train in a first orientation according to one embodiment.

FIG. 14B is a schematic side view of gears of a drive train in a second orientation according to one embodiment.

FIG. 15 is a perspective cut-away view of a solar cell array module according to one embodiment.

FIG. 16 is a graph illustrating the sun's path on the earth as a function of elevation and azimuth.

FIG. 17 is a perspective view of a slew speed reducer connected to a longitudinal support according to one embodiment.

FIG. 18 is a perspective view of a terrestrial solar tracking photovoltaic array according to one embodiment.

FIG. 19 is a perspective view of a slew speed reducer connected to a longitudinal support according to one embodiment.

FIG. 20 is a perspective view of a slew speed reducer connected to a longitudinal support according to one embodiment.

FIG. 21 is a schematic side view of a slew speed reducer according to one embodiment.

FIG. 22 is another schematic side view of a slew speed reducer according to one embodiment.

FIG. 23 is a perspective view of a slew speed reducer connected to a vertical support and a longitudinal support according to one embodiment.

FIG. 24 is a perspective view of a slew speed reducer adapter according to one embodiment.

FIG. 25 is a perspective view of a slew speed reducer at a first position according to one embodiment.

FIG. 26 is a perspective view of a slew speed reducer at a second position according to one embodiment.

FIG. 27 is a perspective view of a slew speed reducer at a third position according to one embodiment.

### DETAILED DESCRIPTION

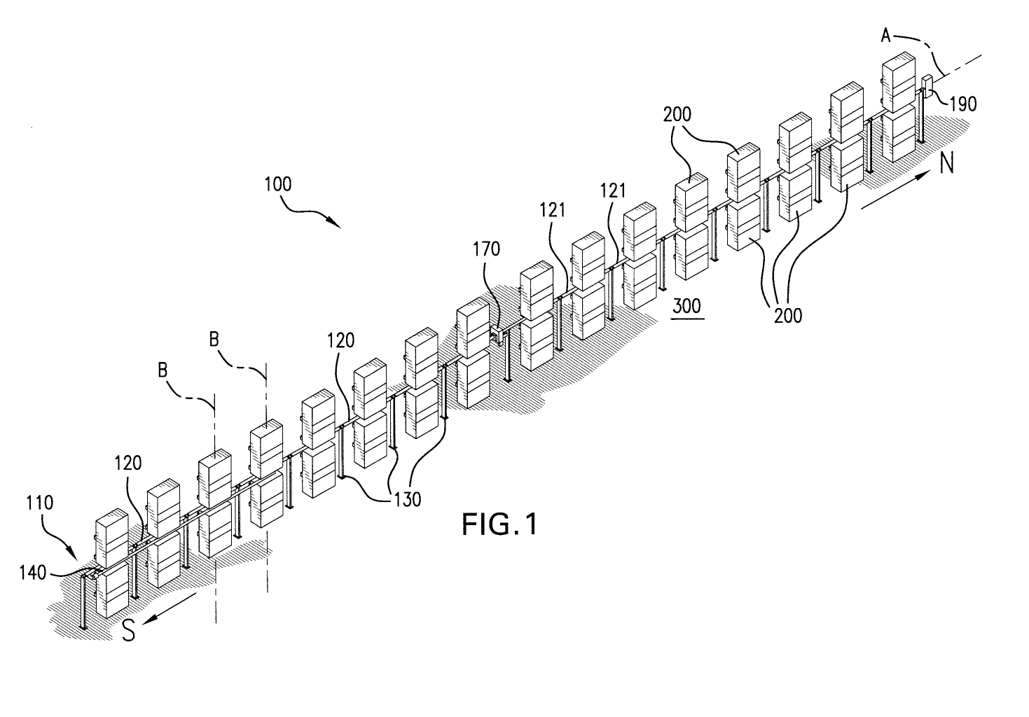

The present application is directed to a terrestrial solar tracking photovoltaic array. FIG. 1 illustrates an embodiment of an array generally illustrated as element 100. The array 100 includes an elongated frame 110 configured to mount solar cell modules 200 in a longitudinally-extending and spaced-apart arrangement. The frame 110 is able to rotate each of the solar cell modules 200 along a first axis A to simultaneously track the elevation of the sun during the course of a day. The frame 110 is able to rotate each solar cell module 200 along axes B that are substantially perpendicular to axis A to track the azimuthal position of the sun during the course of the day.

Frame 110 positions the solar cell modules 200 to track the movement of the sun. Frame 110 includes a longitudinal support 120 that is positioned above a surface 300 by spaced-apart vertical supports 130. In one embodiment, the longitudinal support 120 is a single continuous piece. In one specific embodiment, the longitudinal support 120 is a pipe with a diameter of about 4-5.63 inches and includes a thickness of about 0.167-0.188 inches. The pipe has a length of about 170″ and weighs about 110 lbs.

In another embodiment, the longitudinal support 120 may be constructed from a number of discrete sections 121 that are connected together in an end-to-end arrangement. The lengths and construction of each section 121 may be the same or may be different. In one embodiment, each section 121 is sized to mount a pair or multiple pairs of solar cell array modules 200. The modular design provides for a user to construct the longitudinal support 120 to a length needed to support a necessary number of solar cell modules 200. Sections 121 may be added to an existing frame 110 to accommodate additional solar cell modules 200 as is necessary for the array 100 to produce the desired power output.

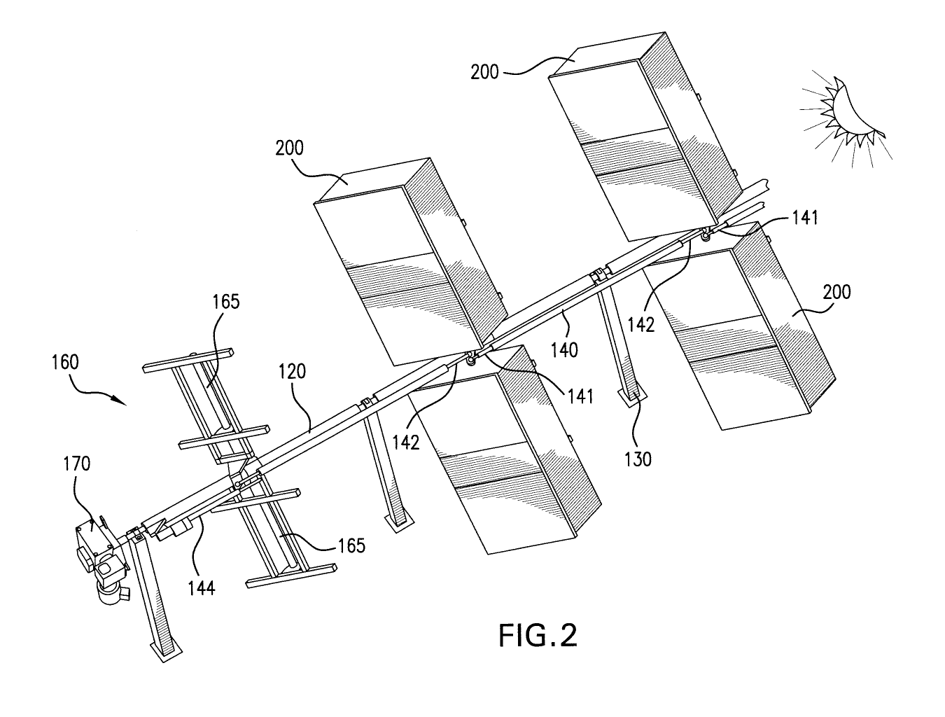

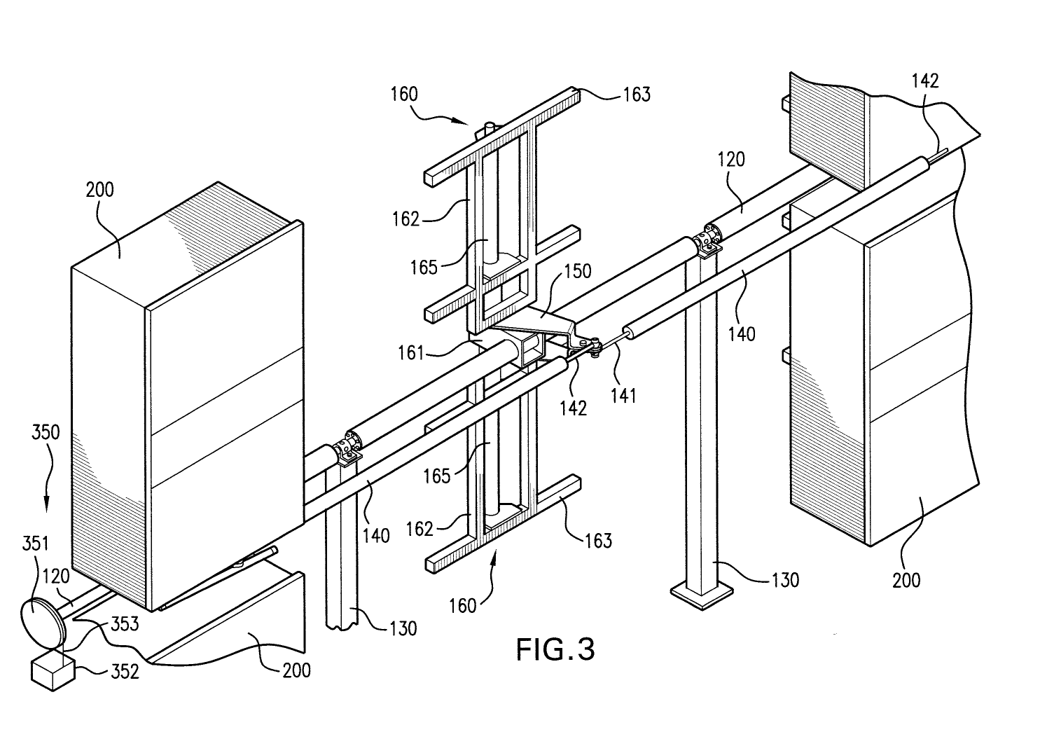

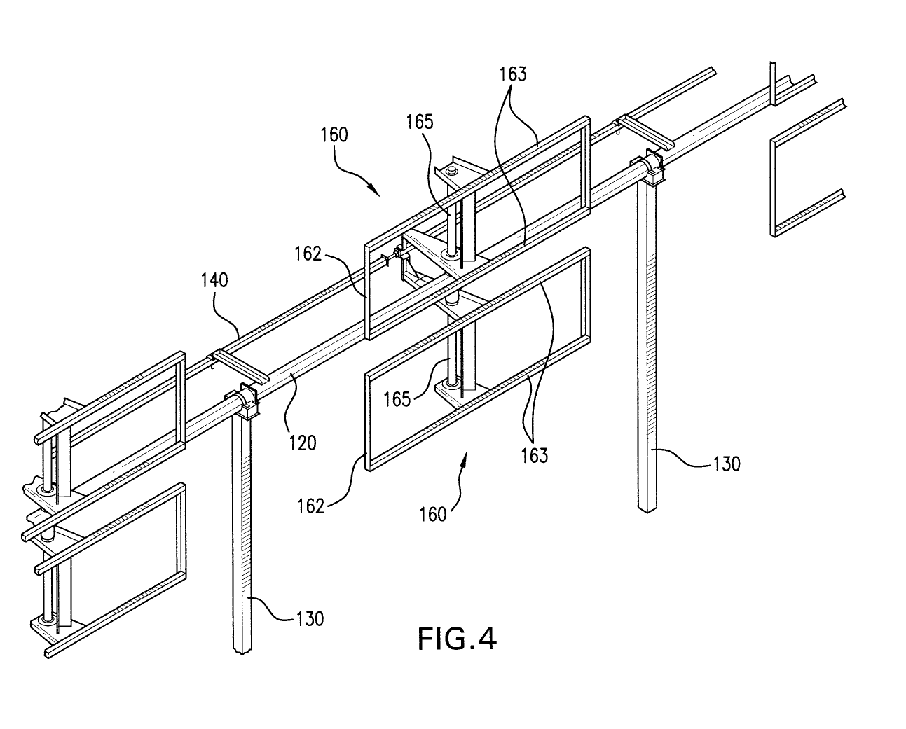

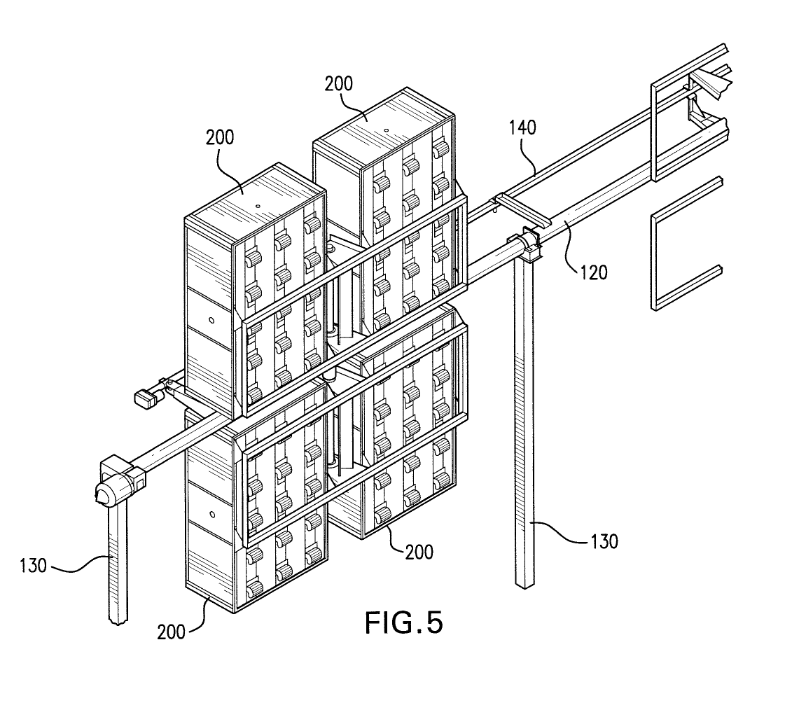

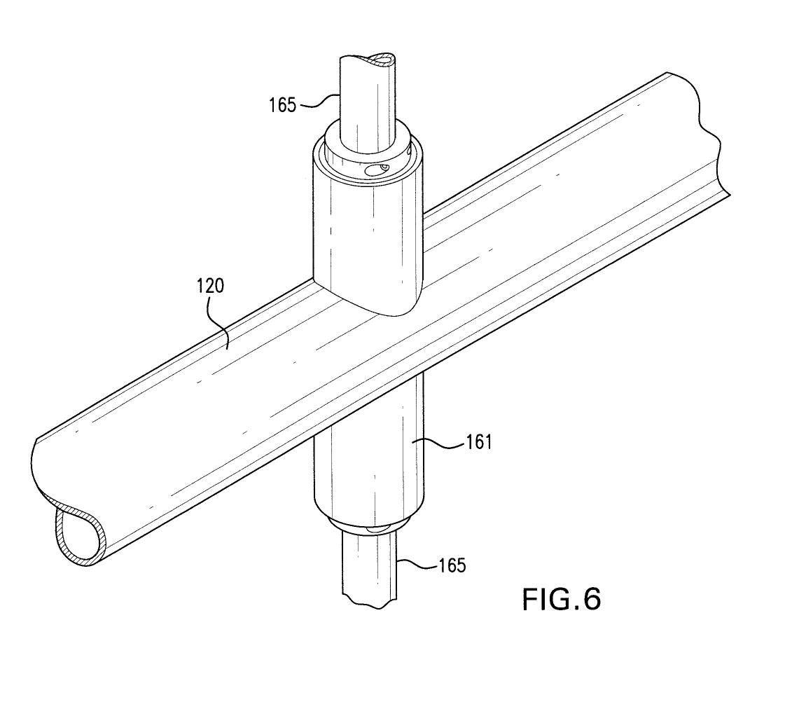

Mounts 160 support the solar cell modules 200 and are connected to the longitudinal support 120. Mounts 160 may be connected to the longitudinal support 120 at least in part through a base 161 as best illustrated in FIGS. 3 and 6. The mounts 160 may include vertical members 162 and horizontal members 163 that support the solar cell modules 200. Mounts 160 may be of different sizes to accommodate different numbers of solar cell modules 200. FIGS. 2 and 3 include the mounts 160 sized to each attach to one solar cell module 200. FIGS. 4 and 5 include mounts 160 sized to receive two solar cell modules 200.

Mounts 160 may also include a pivot member 165 that facilitates pivoting motion of the solar cell modules 200 about second axes B as will be explained in detail below. Pivot member 165 may extend through the base 161, or may be located away from the base 161. Further, the pivot member 165 may be a single elongated member or may be constructed of separate members that are positioned in an end-to-end orientation and connected at the base 161.

The mounts 160 may be positioned at various spacings along the length of the longitudinal support 120. FIGS. 2-5 include the mounts 160 aligned along the longitudinal support 120 in offsetting pairs on opposing sides of the longitudinal support 120 directly across from one another. Other offset positioning may include the mounts 160 unevenly spread along the length with equal numbers of mounts 160 extending outward from each opposing side of the longitudinal support 120. The offset positioning assists to balance the array 100 and facilitate rotation about the first axis A. Other configurations may include uneven numbers of mounts 160 extending outward from the opposing sides of the longitudinal support 120.

The vertical supports 130 are spaced apart along the length of the longitudinal support 120. The vertical supports 130 include a length adequate to position the solar cell modules 120 above the surface 300 for rotation about the first axis A. Therefore, the vertical supports 130 are longer than a height of the mounts 160 and the solar cell modules 200.

The vertical supports 130 are positioned along the longitudinal support 120 away from the mounts 160 to prevent interference with the movement of the solar cell modules 200. As illustrated in FIG. 1, the vertical supports 130 are spaced-apart from the solar cell modules 200 along the length of the longitudinal support 120. In this arrangement, the vertical supports 130 are in a non-overlapping arrangement with the solar cell modules 200. Various numbers of vertical supports 130 may be positioned along the length of the longitudinal support 120. In the embodiment of FIG. 1, a vertical support 130 is positioned between each pair of mounts 160. In other embodiments, the vertical supports 130 are spaced a greater distance apart along the longitudinal support 120. In one specific embodiment, the vertical supports 130 include a 4 inch by 4 inch rectangular shape, and include a thickness of about 0.188 inches. The vertical supports 130 may also be supported in a concrete pad.

A drive 170 is connected to the longitudinal support 120 to provide a force to rotate the longitudinal support 120 about axis A. In one embodiment, drive 170 may be positioned at an end of the longitudinal support 120. Drive 170 may include a drive train with one or more gears that engage with the longitudinal support 120. Additional drives 170 may be connected along the length of the longitudinal support 120 to provide additional rotational force.

A coupling 150 is attached to each mount 160 to enable the mount 160 and attached solar cell modules 200 to rotate about the second axis B. As best illustrated in FIGS. 3, 7, and 8, couplings 150 include first and second arms 151, 152 that are positioned on opposing sides of the base 161. The first arm 151 is operatively connected to a first mount 160, and the second arm 152 is operatively connected to a second mount 160. The arms 151, 52 are connected together at a neck 153. Arms 151, 152 may be constructed from separate pieces that are connected together with a fastener 154 that extends through the neck 153.

The couplings 150 are connected to rotate about the first axis A during rotation of the longitudinal support 120. The couplings 150 are also attached in a manner to rotate about the second axis B with the mounts 160. Because the arms 151, 152 are not connected to the base 161, the coupling 150 moves relative to the base 161 and longitudinal support 120 during rotation about the second axis B. In one embodiment, the arms 151, 152 are connected to the pivot member 165 that extends along a rear of the mounts 160.

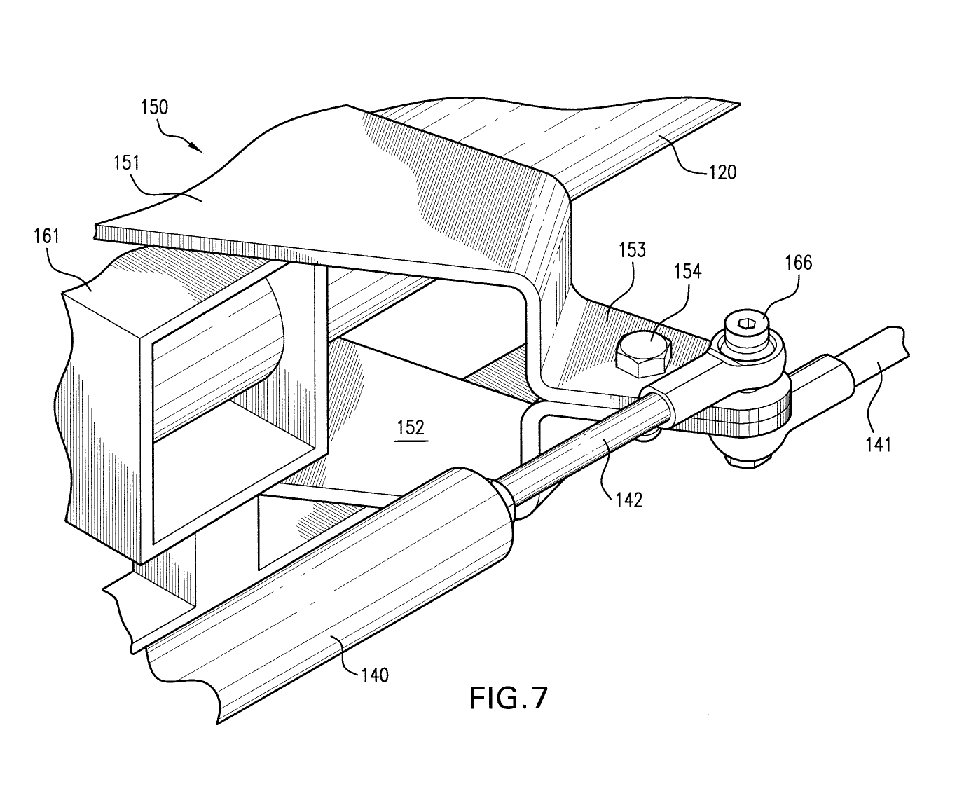

Linkages 140 are connected to the mounts 160 for rotating the solar cell modules 200 about the second axes B. Each linkage 140 includes a first end 141 and a second end 142. The linkages 140 are attached together in a string aligned substantially parallel to the longitudinal support 120. FIGS. 3 and 7 include an embodiment with each coupling 150 attached to two separate linkages 140. Specifically, a first end 141 of a first linkage 140 and a second end 142 of a second linkage 140 are each connected to the coupling 150. The ends 141, 142 of the adjacent linkages 140 may be connected together by a common fastener 166 that extends through the neck 153 of the coupling 150.

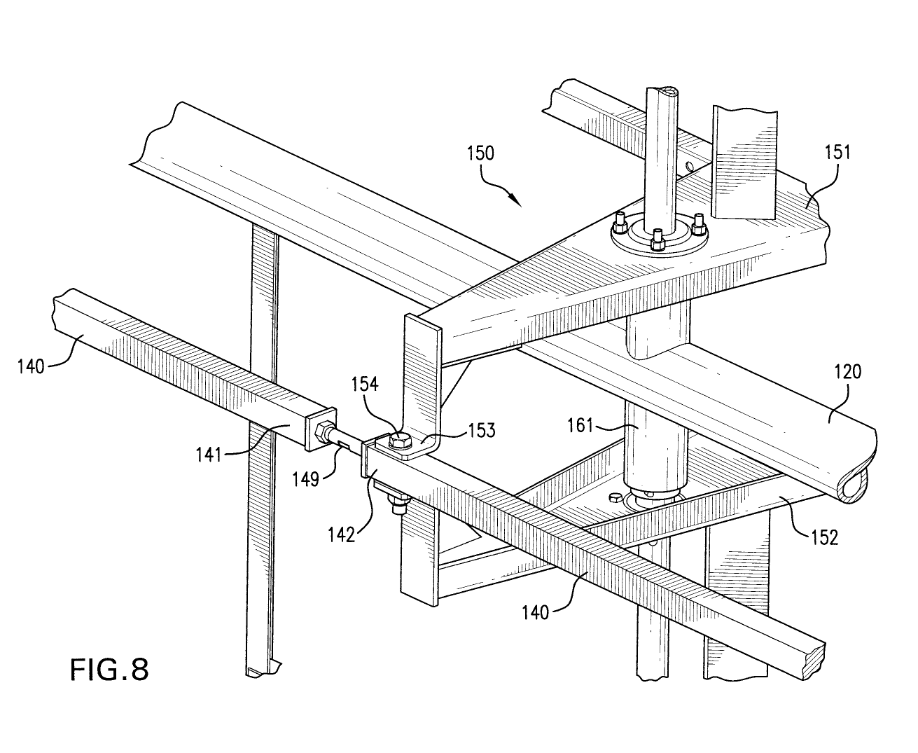

FIG. 8 includes an embodiment with a single linkage 140 connected to the coupling 150. The end 142 is positioned between the arms 151, 152 and connected with a fastener 154. The adjacent linkage 140 is positioned in an end-to-end orientation and spaced away from the coupling 150. A connector 149 connects the linkages 140 together in the end-to-end orientation.

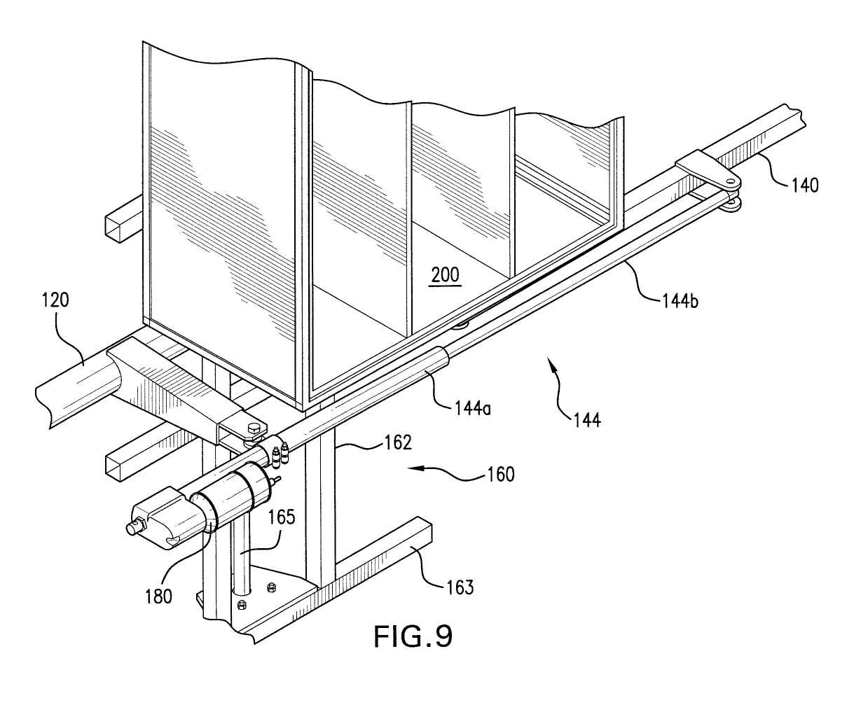

A drive 180 is attached to a drive linkage 144 as illustrated in FIG. 9. The drive linkage 144 includes a first section 144a and a telescoping second section 144b. The first section 144a is operatively connected to the drive 180, and the second section 144b is operatively connected to a linkage 140. The drive 180 provides a force for moving the drive linkage 144 and the attached linkages 140 and thus pivoting the solar cell modules 200 about the second axes B. The number of linkages 140 in the string that is moved by the drive 180 and the drive linkage 144 may vary depending upon the context of use. In one embodiment, one or more additional drives 180 are positioned along the linkage string that work in combination with the drive 180 to move the linkages 140.

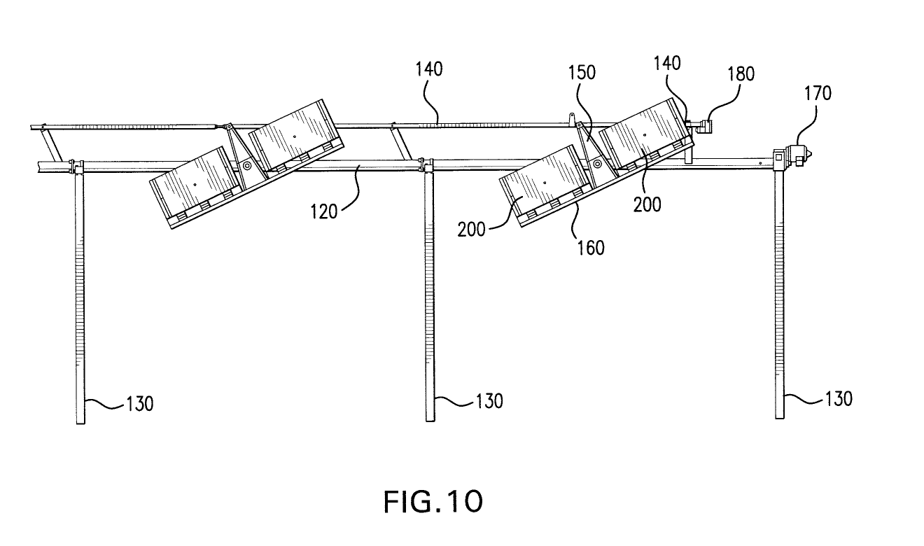

FIG. 10 includes an embodiment with the drive linkage 140 connected to one or more mounts 160 adjacent to the drive 180. The mounts 160 are operatively connected to a linkage 140 through a coupling 150 as described above. The drive 180 directly rotates the mounts 160 with the rotational force being applied to the other, downstream linkages 140 through the coupling 150.

The array 100 is constructed to facilitate rotation of the longitudinal support 120 about the first axis A. The array 100 is designed to balance the power load requirements of the drive 170 during rotation through the various angular positions about the first axis A. One manner of balancing the load requirements is placing the mounts 160 and solar cell modules 200 such that a center of gravity of the array 100 is aligned with the longitudinal support 120. FIGS. 1 and 5 each illustrate examples of this positioning with equal numbers of mounts 160 and solar cell modules 200 extending outward from the opposing sides of the longitudinal support 120. FIGS. 1 and 5 illustrate the mounts 160 and solar cell modules 200 aligned in pairs that are directly across the longitudinal support 120 from each other. Other spacings may include the mounts 160 and solar cell modules 200 being unpaired and scattered along the length. The balanced system maintains a near constant potential energy as rotation in a first direction is facilitated by the weight of the mounts 160 and solar cell modules 200 that extend outward from a first side, and rotation in a second direction is facilitated by the opposing mounts 160 and solar cells 200 that extend outward from a second side of the longitudinal support 120.

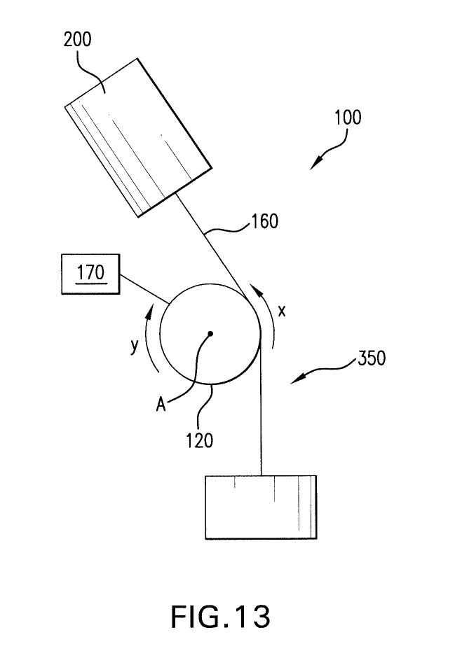

FIG. 13 illustrates a schematic end view of the array 100 with one or more solar cell modules 200 connected to the longitudinal support 120. The drive 170 is connected to rotate the longitudinal support 120 and the modules 200 about the longitudinal axis A to track the elevation of the sun during the course of the day. The drive 170 rotates the longitudinal support to track the sun from a starting point at a beginning of the day to an ending point at the end of the day. In the embodiment of FIG. 13, the drive 170 rotates the longitudinal support in a counterclockwise direction indicated by arrow X during the course of the day. Prior to the start of the next day, the drive rotates the longitudinal support 120 in the opposite direction indicated by arrow Y (i.e., clockwise direction as illustrated in FIG. 13). The rotation in the second direction Y prepares the array 100 for tracking the elevation of the sun during the following day. In one embodiment, the drive 170 takes only a short period of time (e.g., several minutes) to rotate the array in the second direction from the ending point to the starting point.

During an initial period of the day, the weight of the array 100 is such that the drive 170 applies a force to rotate the array 100 in the direction X. At some point during the day, the distribution of mass of the array 100 shifts and the weight tends to rotate or pull the array 100 in the direction X. This shifting that causes the array to tend to rotate forward is referred to as backlash. In one embodiment, once this occurs, the drive 170 applies a braking force to slow the rotation such that the array 100 continues to track the elevation of the sun during the remainder of the day. In one embodiment, this point starts immediately after the solar cell modules 200 reach a specific rotational position, such as but not limited to a top-dead-center rotational position relative to the longitudinal support 120. When this occurs, the weight of the array 100 causes a strain on the drive 170 as the drive 170 now acts against the pulling force of the array 100. This may negatively affect the positional accuracy of the array 100 causing the modules 200 to become out of alignment with the sun during the course of the day.

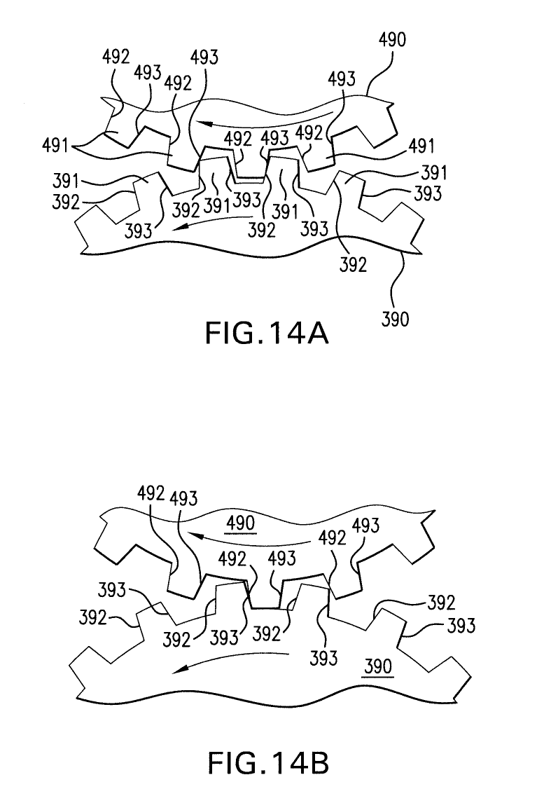

Further, this backlash shift could cause gears in the drive 170 and/or the longitudinal support 120 to become disengaged. FIGS. 14A and 14B illustrate the orientations of the gears 390, 490. Gear 390 is operatively connected to the drive 170 and engages with gear 490 operatively connected to the longitudinal support 120. Gears 390, 490 may be the only two gears of a drive train that connects the drive 170 with the longitudinal support 120, or may be two of a more extensive drive train. Gear 390 includes a plurality of teeth 391 spaced around the perimeter each with a first edge 392 and a second edge 393. Likewise, gear 490 includes a plurality of teeth 491 each with first and second edge 492, 493. Gears 390, 490 may be substantially similar, or may include different sizes, number of teeth, and/or teeth spacing depending upon the context of use.

FIG. 14A illustrates the orientation when the drive 170 applies a force to rotate the longitudinal support 120. The first edges 392 of the teeth 391 of gear 390 contact against the second edges 493 of the teeth 419 of gear 490. This contact transfers the force of the drive 170 through the gears 390, 490 to rotate the longitudinal support 120.

In the event of a backlash shift as illustrated in FIG. 14B, the rotational speed of gear 490 is greater than the rotational speed of gear 390. This causes gear 490 to rotate ahead of gear 390 and there is no longer contact between edges 392 and 493. Gear 490 rotates ahead with the first edges 492 contacting against the second edges 393. In some instances, this contact causes the gear 490 to actually drive gear 390 until the array 100 settles to an equilibrium position. This causes the solar cell modules 200 to become misaligned with the sun. In one embodiment, the array 100 rotates forward an amount with the solar cell modules 200 being located vertically below the longitudinal support 120.

To prevent this from occurring, a balancing or dynamic anti-backlash mechanism 350 may be connected to the array 100. FIG. 13 schematically illustrates a mechanism 350 that applies a force to the array 100 to urge rotation in the second direction Y. The mechanism 350 provides for the drive 170 to drive the longitudinal support with the surfaces 392 on gear 390 remaining in contact with the surfaces 493 of gear 490.

FIG. 3 illustrates a dynamic anti-backlash mechanism 350 that includes a pulley 351, weight 352, and cable 353. The pulley 351 is connected to the longitudinal support 120. FIG. 3 illustrates the pulley 351 at the end of the longitudinal support 120, although other embodiments may position the pulley 351 at different locations along the length. The weight 352 is attached to the pulley 351 by the cable 353. The weight 352 hangs downward from the pulley 351 and may ride along guide rails (not illustrated). The cable 353 may include a variety of lengths and constructions, including rope, chain, and braided wire.

In use, the weight 352 may be spaced a distance from the longitudinal support 120 at the start of the day. As the day progresses, the drive 170 rotates the longitudinal support 120 in a first direction causing the cable 352 to wrap around the pulley 351 and move the weight upward towards the longitudinal support 120. The mechanism 350 applies a counterbalance force to the array 100 to counteract the backlash weighting that may occur at some point during the day. At the end of the day, the weight 352 is positioned in closer proximity to the longitudinal support 120. Prior to beginning tracking during the next day, the drive 170 rotates the longitudinal support in a second opposite direction. This causes the cable 353 to unwind from the pulley 351 and the weight 352 to move downward away from the longitudinal support 120. This force applied by the mechanism 350 to the array 100 assists the drive 170 in rotating the array 100 back to the starting position.

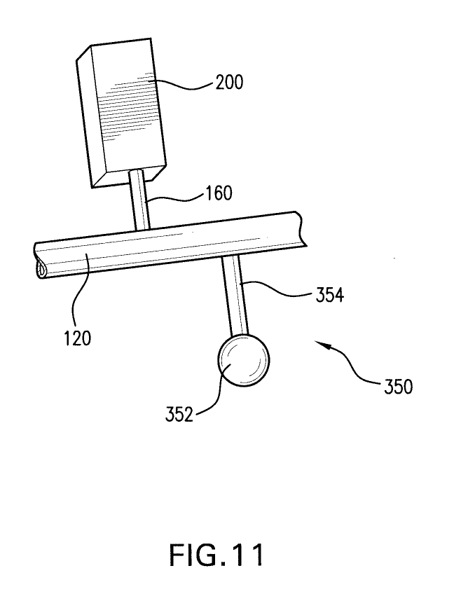

FIG. 11 includes an anti-backlash mechanism 350 with the weight 352 positioned on a rigid support 354 that extends outward from the longitudinal support 120. The amount of the weight 352 and the length of the support 354 are configured to assist the drive 170 in rotation of the array 100.

The dynamic anti-backlash mechanisms 350 may be configured for the drive 170 to apply a constant torque to the longitudinal support 120 during rotation in the first direction. The drive 170 may further include a controller to apply a constant torque to the longitudinal support 120.

The dynamic anti-backlash mechanisms 350 may balance an unbalanced array 100. The uneven balancing may be caused by and uneven number of mounts 160 and solar cell modules 200 on one side of the longitudinal support 120. The amount of the weight 352 and length of the support 354 are determined to counterbalance the otherwise uneven weight distribution on the longitudinal support 120.

The balanced weighting of the array 100 eliminates or reduces weight loading and frictional loading issues with the drive 170. This reduces power requirements for the drive 170 and frictional wear on the drive train. The balanced weighting may also improve tracking of the array 100 due to reduced strain in the drive 170 and drive train.

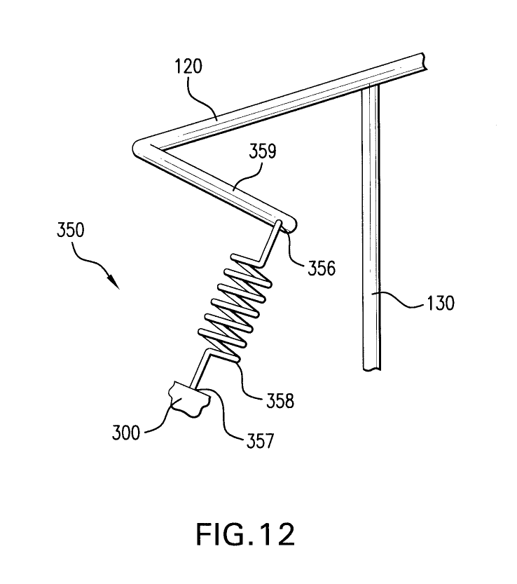

The dynamic anti-backlash mechanism 350 may also include one or more tension members connected to the longitudinal support 120. FIG. 12 includes an embodiment with a tension member 358 operatively connected to the longitudinal support 120. The tension member 358 includes a first end 356 attached to the longitudinal support 120, and a second end 357 anchored at a point away from the longitudinal support such as on the surface 300, vertical support 130, or other. An extension arm 359 may extend outward from the longitudinal support 120 and provide an attachment point for the first end 356 away from the longitudinal support 120. In use, rotation of the longitudinal support 120 causes the tension member 358 to elongate and apply a return force. The tension member 358 may apply a greater force the farther the longitudinal member 120 rotates to offset the increasing weight offset caused by rotation of the array 100. The tension member 358 may further include a coil spring that extends around the longitudinal support. One of the first and second ends 356, 357 is attached to the longitudinal support 120. Rotation of the longitudinal support 120 causes the tension member 358 to again provide a return force.

In one specific embodiment, the dynamic anti-backlash mechanism 350 includes two tension springs each with a 160 lb maximum force that are anchored to one of the vertical supports 130. The longitudinal support 120 includes a sprocket that is connected to the springs with a chain. In one embodiment, the sprocket is a Martin 50A65 sprocket, and the chain includes three feet of #50 chain. During the course of the day, the dynamic anti-backlash mechanism 350 applies varying amounts of force as the array moves to track the sun. In the morning, the moment created by the array 100 acts counterclockwise and the dynamic anti-backlash mechanism 350 works as an anti-backlash device with the springs in a relaxed condition and contributing very little force. By noon, the array 100 is practically balanced and the springs produce about half of the force (about 80 lbs each in the embodiment of the 160 lb springs) creating a counterclockwise anti-backlash moment. Later in the afternoon, the moment created by the array 100 changes polarity and acts in the opposite direction with the springs producing near full force that is capable to overpower the force in the opposite direction and still act as an anti-backlash mechanism.

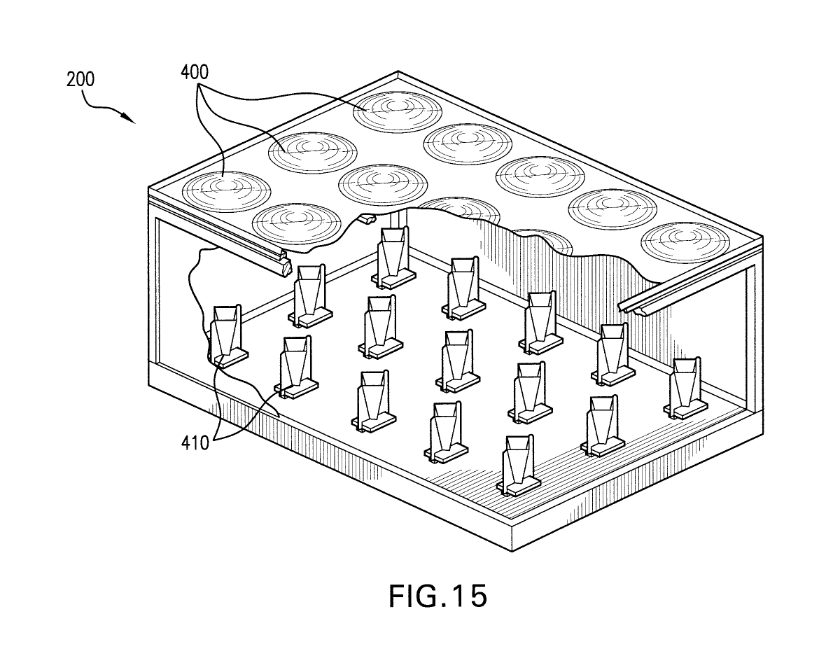

In one embodiment, the solar cell modules 200 are each about 43″ by 67″. FIG. 15 illustrates an embodiment of a solar cell module 200 with an aluminum frame and plastic or corrugated plastic sides that reduce the overall weight to about 70 pounds. In one embodiment, each solar cell module 200 includes a 3×5 array of lenses 400 that are positioned over corresponding receivers 410. The lenses may include various shapes and sizes with one specific embodiment including lenses that are about 13″ square. Further, the focal length between the lenses 400 and the receivers 410 is about 20″. Each receiver 410 may include one or more III-V compound semiconductor solar cells.

When mounted on the surface 300, the longitudinal support 120 may be positioned in a north N-south S orientation as illustrated in FIG. 1. In one embodiment, the surface 300 is the surface of the Earth. The longitudinal support 120 includes a length to space a desired number of solar cell modules 200. Throughout the course of the day, the array 100 is adjusted to maintain the solar cell modules 200 facing towards the sun. The drive 170 may be periodically activated to provide a force to rotate the longitudinal support 120 and hence each of the mounts 160 and attached solar cell modules 200. The force applied by the drive 170 provides for each of the solar cells receivers 200 to be moved a same amount such that each solar cell array module 200 is synchronized and move in unison. Rotation of the longitudinal support 120 may provide for the solar cell modules 200 to track the elevation of the sun during the course of the day.

In addition to the rotation of the longitudinal support 120, the one or more drives 180 move the linkages 140 to further maintain the solar cell modules 200 aligned with the sun. The drive(s) 180 are periodically activated to move the first linkage 140a and attached string of linkages 140. This movement causes the couplings 150 and attached mounts 160 and solar cell modules 200 to pivot about the various axes B. These axes B may be orthogonal to the axis A. The string of linkages 140 provides for each of the solar cell modules 200 to again move in unison about their respective axis B. The movement about the B axes may allow the solar cell modules 200 to track the azimuthal position of the sun during the course of the day.

A controller 190 may control the movement of the terrestrial solar tracking array 100. The controller 190 may include a microcontroller with associated memory. In one embodiment, controller 190 includes a microprocessor, random access memory, read only memory, and in input/output interface. The controller 190 controls operation of the one or more drives 170 for rotating the longitudinal support 120 and the solar cell modules 200 about the first axis A. The controller 190 further controls the one or more drives 180 for driving the linkages 140 and rotating the solar cell modules about the second axes B. The controller 190 may include an internal timing mechanism such that the operation of the drives corresponds to the time of day for the solar cell modules 200 to track the azimuth and elevation of the sun.

The shadow cast by a given solar cell module 200 depends on its size and shape, and also on its location relative to the location of the sun in the sky. In the East-West direction, the sun location can vary by up to 150°. In this connection, it should be noted that it is generally accepted that, where the elevation of the sun is below 15° above the horizon, its rays are of insufficient strength to generate a useful amount of electricity. The latitude at which the solar cell array 100 is positioned is, therefore, of little influence.

In the North-South direction, the sun location varies by 46°, given that the earth's axis is tilted at an angle of 23° with respect to its orbit around the sun. In this connection, it will be appreciated that latitudes below 23° are subject to different conditions, and that latitudes above 45° are probably not relevant due to poor direct normal insolation (DNI) levels.

The solar cell array 100 is constructed in a manner to eliminate or minimize shadowing problems between solar cell modules 200. In one embodiment, the longitudinal support 120 and the individual sections 121 of the solar cell modules 200 are sized to space apart each module 200 such that it is fully illuminated for positions where the sun is 15° above the horizon, and that there is no shadowing of any given module 200 by any other module 200.

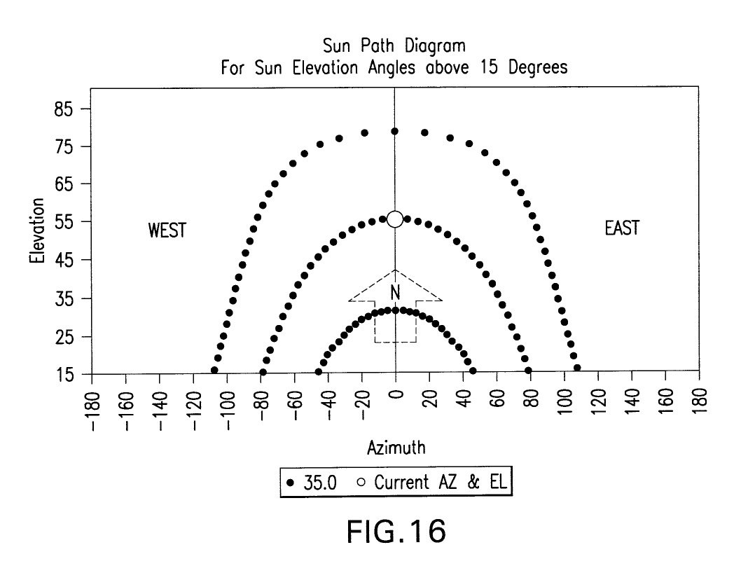

FIG. 16 is a sun path diagram showing the elevation of the sun for all angles above 15° at a latitude of 35° North. The graph shows the sun path for three times of the year, namely at the summer solstice (indicated by the highest dotted line), at the winter solstice (indicated by the lowest dotted line), and at the equinoxes (indicated by the middle dotted line). At all other dates, the sun path falls within the envelope defined by the highest and lowest dotted lines. Thus, at the winter solstice, the sun path goes from a negative azimuth angle of about 45° to a positive azimuth angle of about 45°, and from an elevation of 15° to about 27°, and then back to 15°. Similar ranges are apparent for a sun path at the summer solstice and at the equinoxes.

U.S. Pat. No. 7,381,886 assigned to Emcore Corporation discloses solar cell arrays and positioning relative to the sun path and is herein incorporated by reference in its entirety.

In one embodiment, the terrestrial solar tracking array 100 can be installed in a straight-forward manner. The various components are sized to fit within a standard vehicle and are light-weight to allow installation by a single person or limited number of persons. Further, the modular aspect of the array 100 facilitates modifications after the initial installation. Additional sections 121 and vertical supports 130 may be added to the frame 110 to accommodate a desired number of additional solar cell modules 200. Further, the size of the array 100 may be reduced after installation by removing one or more solar cell modules 200. One or more dynamic anti-backlash mechanisms 350 may be added to the array 100 as necessary. In one embodiment, additional mechanisms 350 are added when the size of the array 100 is increased to accommodate additional solar cell modules 200. Further, the weight 352 or number or sizes of the biasing mechanisms may be altered to provide the necessary balancing forces.

A slew speed reducer 500 may rotate the longitudinal support 120. The slew speed reducer 500 may deliver high torque and smooth rotational positioning to the longitudinal support 120 to accurately maintain the alignment of the solar cell modules 200 during the course of the day. The slew speed reducer 500 may also rotate heavier and/or larger solar cell modules 200 and supporting framework than other drives. The slew speed reducer 500 may also include a reduced size that does not interfere with the movement of the other elements of the solar cell array 100.

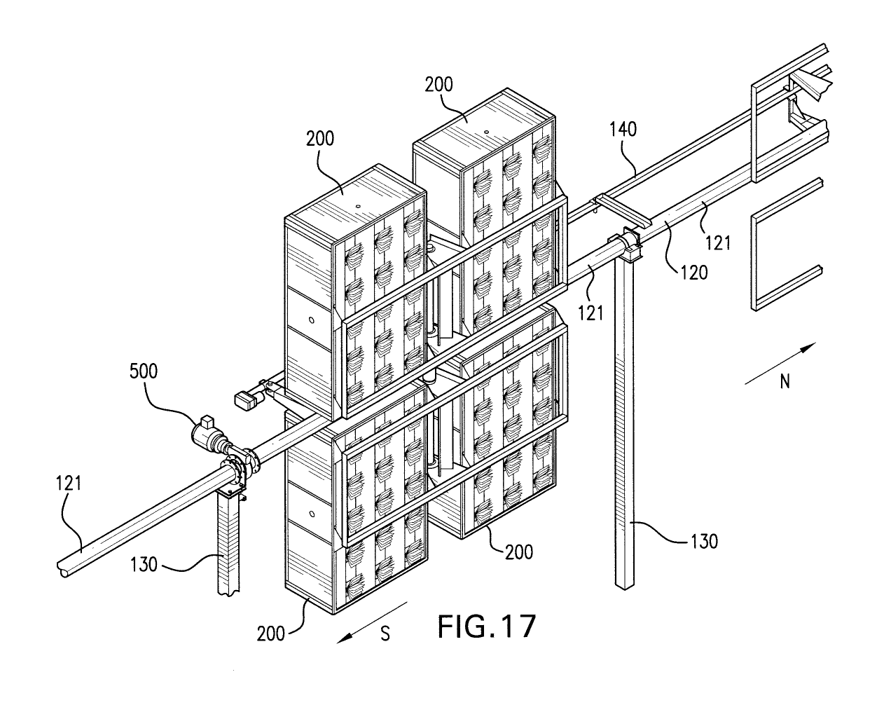

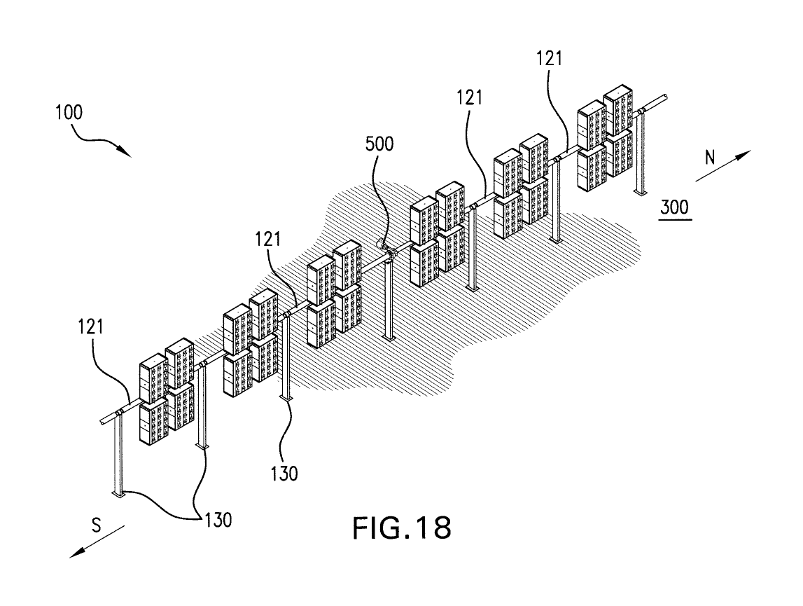

The slew speed reducer 500 may be positioned along a central section of the longitudinal support 120. As illustrated in FIGS. 17-20, the slew speed reducer 500 may be positioned between discrete sections 121 of the longitudinal support 120. In a specific embodiment, the slew speed reducer 500 is connected at the center of the longitudinal support 120 and applies an equal amount of torque to each half of longitudinal support 120. A single slew speed reducer 500 may be adequate for providing rotational power to the longitudinal support 120. Alternatively, two or more slew speed reducers 500 may provide the rotational power. The slew speed reducer 500 may be used with or without one or more dynamic anti-backlash mechanisms 350.

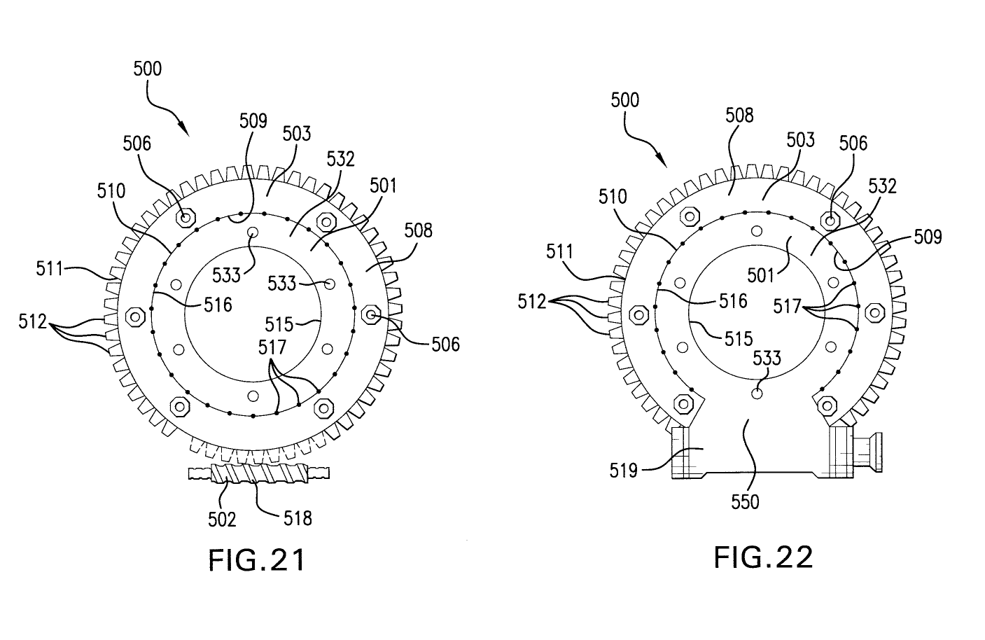

FIGS. 21 and 22 illustrate a slew speed reducer 500 that includes an inner slew ring 501, a worm 502, and an annular outer gear ring 503. The inner ring 501 and outer ring 503 are arranged in an embedded alignment and concentric about a common axis that may include the axis of the longitudinal support 120. The outer gear ring 503 has an inner radial surface 509 and defines a central opening 510 sized to receive the inner slew ring 501. The outer gear ring 503 also has an outer surface 511 with a plurality of teeth 512 that mate with the worm 502. Lateral sides 508 extend on each side of the outer gear ring 503 between the inner and outer surfaces 509, 508. One or more apertures 506 may extend through the lateral sides 508.

The inner slew ring 501 includes an inner radial surface 515 and an outer radial surface 516. The inner slew ring 501 also includes lateral sides 532 that extend between the inner and outer surfaces 515, 516. One or more apertures 533 may extend through the lateral sides 532. Bearings 517 are positioned between the rings 501, 503 to accommodate relative rotation between the rings 501, 503.

The worm 502 is positioned at the outer surface 511 of the outer gear ring 503. The worm 502 includes a helical tooth 518 that engages with the plurality of teeth 512 on the outer gear ring 503. A housing 519 may extend around a portion or entirety of the worm 502. The housing 519 may protect the worm 502 from debris or environmental elements (e.g., ice, rain, snow) to which the array 100 may be exposed.

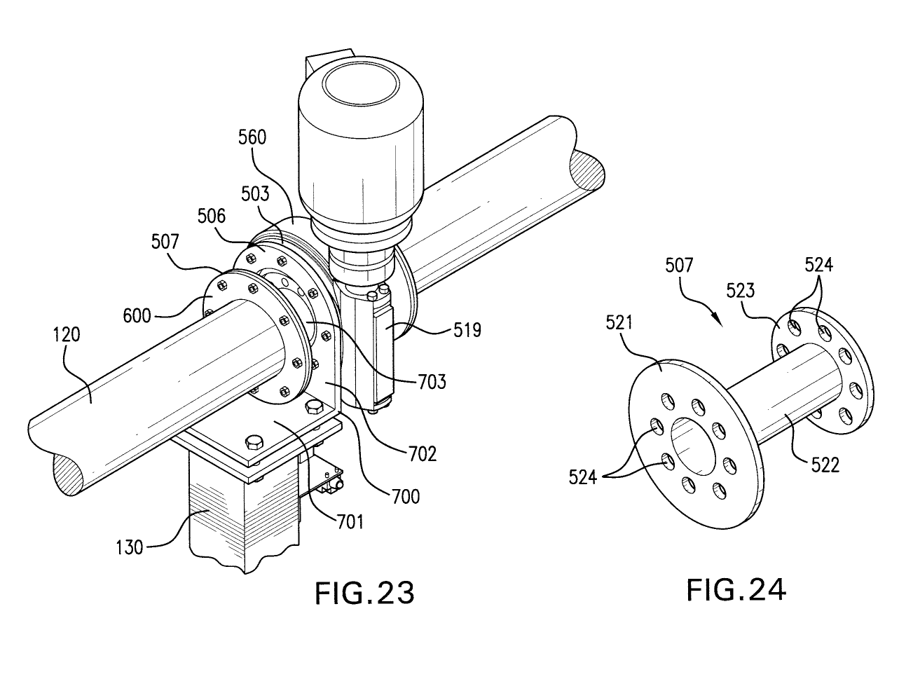

A connecting member 550 connects the worm 502 to the inner slew ring 501 such that the two elements rotate together. FIG. 22 includes the connecting member 550 extending between the housing 519 and the inner slew ring 501. In one embodiment, the connecting member 550 extends on both lateral sides 508 of the outer annular gear ring 503 and is connected to the lateral sides 532 of the inner slew ring 501. As illustrated in FIG. 23, a cover 560 may extend over the teeth 512 of the outer annular gear ring 503.

The inner slew ring 501 is connected to opposing discrete sections 121 of the longitudinal support 120 by adapters 507. A first adapter 507 extends between the inner slew ring 501 and a first discrete section 121, and a second adapter 507 extends between the inner slew ring 501 and a second discrete section 121.

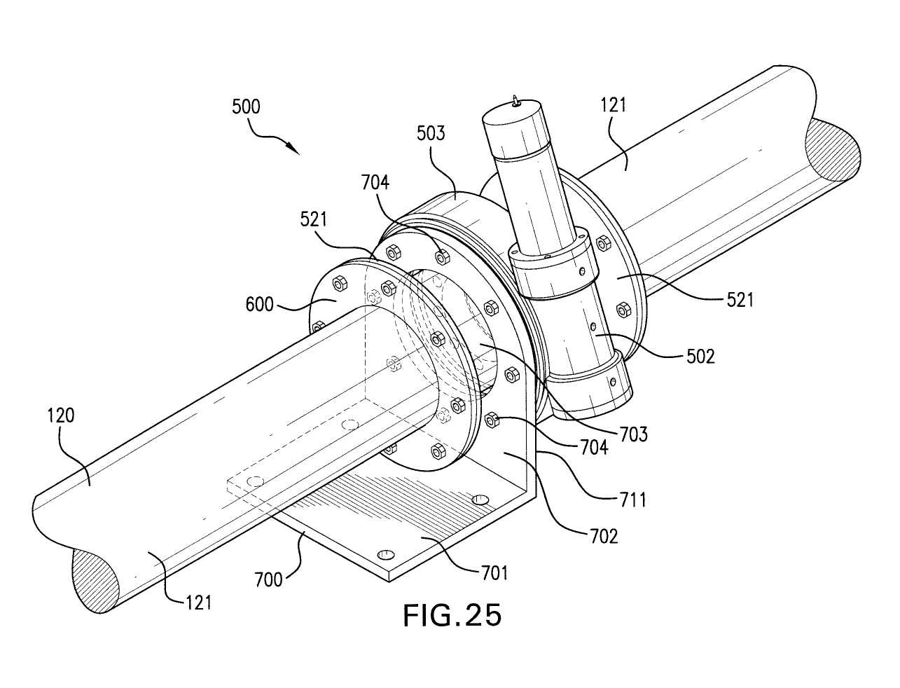

As illustrated in FIG. 24, the adapters 507 each include a first plate 521, a spacer 522, and a second plate 523. FIG. 24 includes the first plate 521 including a larger width than the second plate 523. Other embodiments may include the widths being the same, or may include the first plate 521 with a smaller width. One of the plates 521, 523 is configured to connect to the inner slew ring 501. In one embodiment, plate 523 abuts against the lateral side 532 and includes apertures 524 that align with apertures 533 to receive fasteners to connect the elements together. The second plate 521 is connected to the discrete section 121. In one embodiment as illustrated in FIG. 25, the first plate 521 abuts against a flange 600 mounted to the discrete section 121. The apertures 524 may align with apertures on the flange 600 to receive fasteners to connect the members together. The spacer 522 separates the plates 521, 523 and may include various longitudinal lengths depending upon the context of use.

The second discrete section 121 on the opposing side of the slew speed reducer 500 may be connected in a similar manner. A second adapter 507 extends between and connects the slew speed reducer 500 to the second discrete section 121. The second adapter 507 may be the same or different than the first adapter 507. In another embodiment, one or both discrete sections 121 are connected directly to the inner slew ring 501 (i.e., without an adapter 507).

A bracket 700 connects the slew speed reducer 500 to a vertical support 130 as best illustrated in FIGS. 23 and 25-27. The bracket 700 includes a first section 701 that connects to the vertical support 130, and a second section 702 that connects to the outer gear ring 503. Each of the sections 701, 702 may be substantially flat and perpendicular to each other. The bracket 700 may also include other configurations. The first section 701 may connect to the vertical support 130 by various mechanisms, including fasteners 710 as illustrated in FIG. 23. The second section 702 includes a central aperture 703 that receives the spacer 522 and is sized to allow rotation of the adapter 507 relative to the bracket 700. The second section 702 may also include a face 711 shaped to abut against the lateral side 508 of the outer gear ring 503. Apertures 704 in the second section 702 align with apertures 506 in the outer gear ring 503 to receive fasteners to attach the bracket 507 to the outer gear ring 503. This connection prevents the outer gear ring 503 from rotating during operation of the slew speed reducer 500. With the outer gear ring 503 stationary, slew speed reducer 500 allows inner slew ring 501 and worm 502 to rotate with the longitudinal support 120 while tracking the movement of the sun.

In one embodiment, the outer diameter of the outer gear ring 503 is sized to extend outward beyond the second section 702 of the bracket 700. This exposes the teeth 512 on the outer gear ring 503 and facilitates engagement with the helical tooth 518 of the worm 502.

In use, the slew speed reducer 500 is activated by the controller 190 which rotates the worm 502. The helical tooth 518 engages with the teeth 512 on the outer gear ring 503. The engagement with the fixed outer gear ring 503 causes the worm 502 and the inner slew ring 501 rotate around the outer gear ring 503. The worm 502 and connecting inner slew ring 501 rotate around the outer gear ring 503 because the outer gear ring 503 is fixedly connected to the vertical support 130 through the bracket 700.

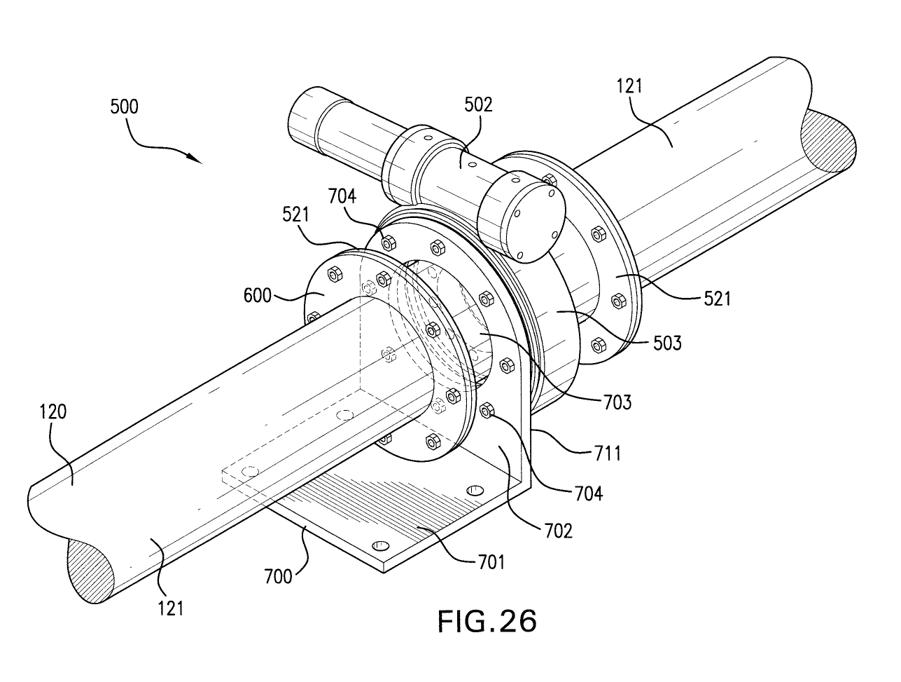

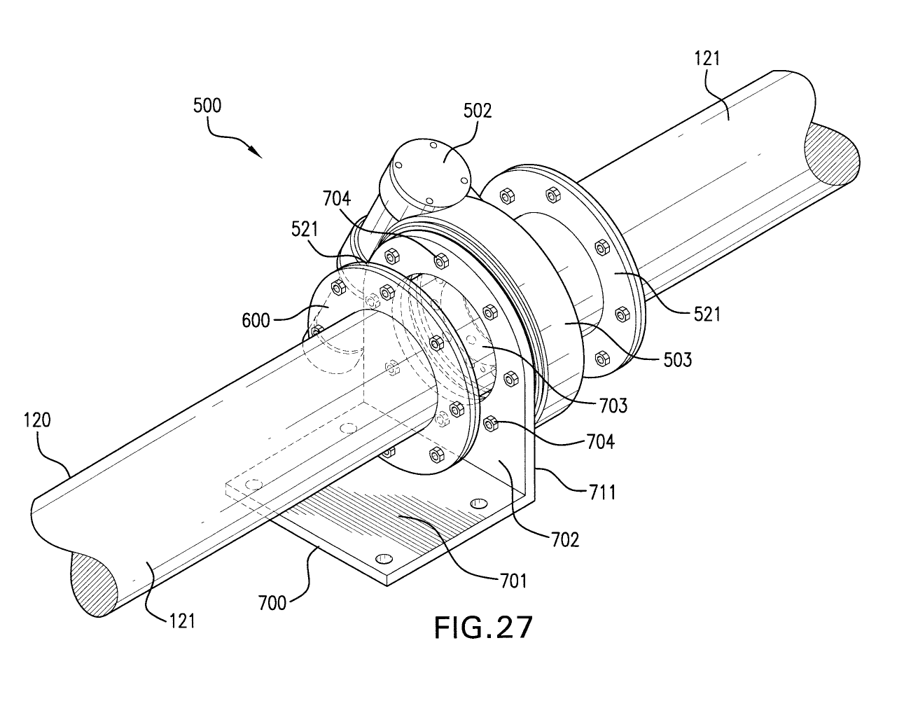

Illustrations of various positions of these elements during the course of operation are illustrated in FIGS. 25-27. In one embodiment, FIG. 25 illustrates the relative position at a first time during the day, FIG. 26 at a later second time, and FIG. 27 at a third even later time. In one embodiment, FIG. 25 illustrates the position at the beginning of the day, FIG. 26 at midday, and FIG. 27 at the end of the day.

The amount of rotation of the worm 502 about the outer gear ring 503 may vary depending upon the specifics of the array 200. In one embodiment, the worm rotates about 180° around the outer gear ring 503. The amount of angular range defining the rotation for array 100 could be different depending on many factors such as, the geographical location of the solar array or the time of year, and could therefore be adjusted at anytime during the installation or operation of the solar tracking array.

The controller 190 may control the movement of the slew speed reducer 500 during the course of the day. At the end of the day, the controller 190 may cause the worm 502 to rotate in an opposite direction to return the array 100 to the starting position in preparation for the subsequent day.

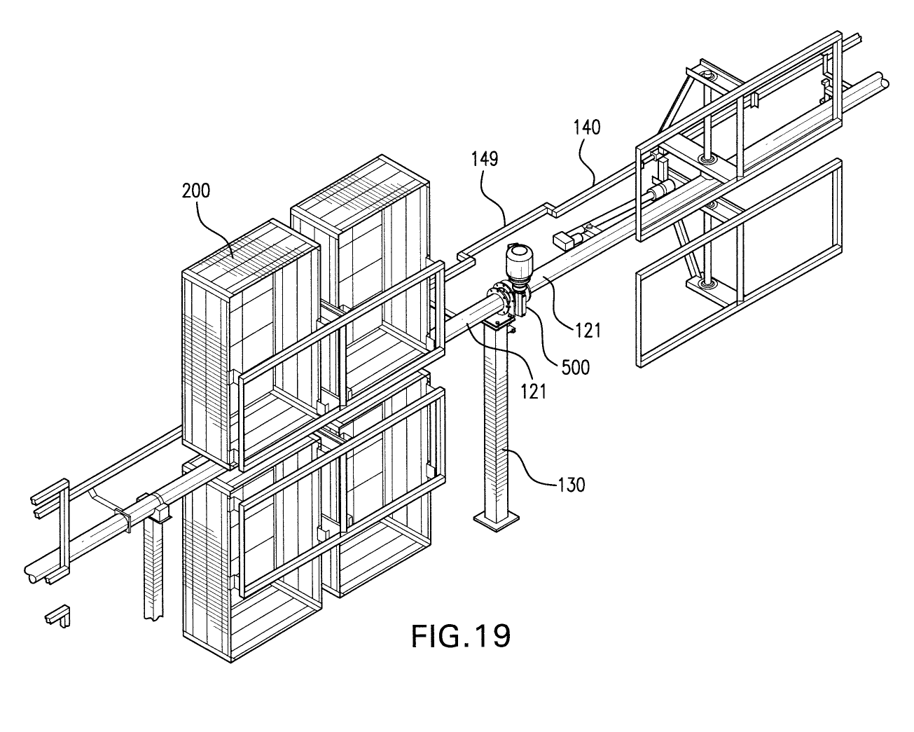

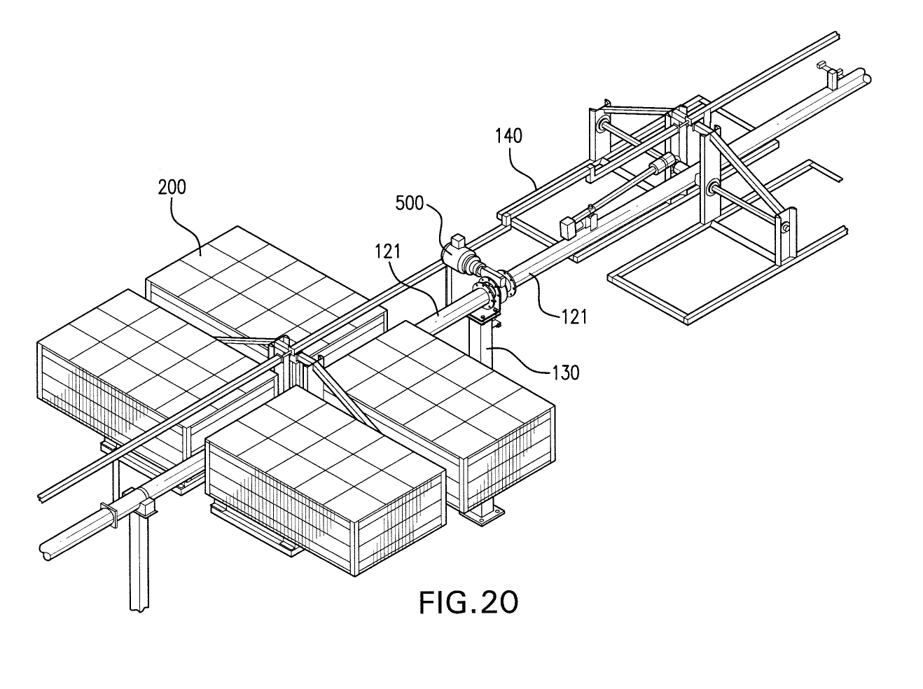

The slew speed reducer 500 is typically designed to have a compact size and low profile such that the movement of the worm 502 and housing 519 does not interfere with the movement of the solar cell modules 200. The positioning and structure of the slew speed reducer 500 may particularly be configured to not interfere with the movement of the linkages 140. FIG. 17 includes positioning of the slew speed reducer 500 away from the linkages 140 that rotate the solar cell modules 200 about the second axes B. Another configuration as illustrated in FIG. 19 includes one or more of the linkages 140 being shaped to provide the necessary clearance with the slew speed reducer 500. FIG. 19 specifically includes a linkage 140 with an offset section 149 positioned adjacent to the slew speed reducer 500. The offset section 149 is spaced a distance away from the slew speed reducer 500 so as to not impede the movement of solar cell modules 200 along axis B. In another embodiment as illustrated in FIG. 20, the slew speed reducer 500 is connected to the linkages 140.

A single slew speed reducer 500 may be adequate to rotate the longitudinal support 120. Alternatively, two or more slew speed reducers 500 may be positioned along the longitudinal support 120 to drive the various discrete sections 121 as necessary.

In one embodiment, the longitudinal support 120 includes one or more tubes that receive torque from the drive 170. Therefore, the longitudinal support 120 and the discrete sections 121 may be referred to as a “torque tubes”.

While particular embodiments of the present invention have been shown and described, it will be understood by those skilled in the art that, based upon the teachings herein, changes and modifications may be made without departing from this invention and its broader aspects and, therefore, the appended claims are to encompass within their scope all such changes and modifications as are within the scope of this invention. Furthermore, it is to be understood that the invention is solely defined by the appended claims.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” “comprise” and variations thereof, such as, “comprises” and “comprising” are to be construed in an open, inclusive sense, that is as “including, but not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

1. A terrestrial solar tracking photovoltaic array comprising:
a longitudinal support extending parallel to the surface of the ground;
a vertical support mounted on the ground for supporting the longitudinal support;
a slew speed reducer positioned along a central section of the longitudinal support, the slew speed reducer including a first portion fixedly connected to the vertical support and a second portion connected to the longitudinal support, the slew speed reducer configured to rotate the second portion and the longitudinal support relative to the first portion about a first axis that extends through a center of the longitudinal support in first and second rotational directions;
a plurality of solar cell array modules connected to and spaced apart along the longitudinal support, each of the solar cell modules comprising a support and a plurality of concentrating lenses positioned over respective optical receivers, each of the receivers comprising a III-V compound semiconductor solar cell; and
a string of linkages spaced apart from the longitudinal support;
the longitudinal support being rotatable about the first axis by the slew speed reducer to track the sun during the course of a day;
the string of linkages being movable along the longitudinal support to rotate each of the plurality of solar cell array modules to track the azimuth of the sun during the course of the day.

2. The terrestrial solar tracking photovoltaic array of claim 1, wherein the slew speed reducer is positioned at a center of the longitudinal support.

3. The terrestrial solar tracking photovoltaic array of claim 1, wherein the first portion of the slew speed reducer includes a first ring and the second portion of the slew speed reducer includes a second ring, the first and second rings being concentric about the first axis and positioned in an embedded configuration.

4. The terrestrial solar tracking photovoltaic array of claim 3, wherein the first ring includes teeth positioned about an exterior surface and the slew speed reducer further includes a worm with a thread that engages with the teeth.

5. The terrestrial solar tracking photovoltaic array of claim 4, wherein the worm is connected to the second ring such that the second ring and the gear rotate relative to the first ring to rotate the longitudinal support about the first axis.

6. The terrestrial solar tracking photovoltaic array of claim 1, wherein the longitudinal support includes first and second discrete sections with the slew speed reducer positioned between the two discrete sections.

7. The terrestrial solar tracking photovoltaic array of claim 6, wherein the first and second discrete sections include the same length.

8. (canceled)

9. A terrestrial solar tracking photovoltaic array comprising:
first and second longitudinal supports extending over the surface of the earth substantially in a north-south direction, the longitudinal supports each including opposing inner and outer ends, the first and second supports positioned in an end-to-end arrangement with the inner ends being positioned together;
a plurality of solar cell array modules including III-V compound semiconductor solar cells pivotably coupled to the longitudinal supports and spaced along a length of the longitudinal supports;
a plurality of vertical supports spaced along the longitudinal supports to elevate the longitudinal supports over the surface of the earth, each of the plurality of vertical supports includes a first end connected to the earth and a second end connected to one of the longitudinal supports, each of the vertical supports being spaced away from each of said solar cell array modules along the longitudinal supports;
a slew speed reducer connected to the inner ends of the first and second longitudinal supports and to one of the vertical supports, the slew speed reducer including first and second portions that are embedded together and a gear that engages one of the first and second portions, the slew speed reducer configured to rotate the longitudinal support about a first axis in a first direction during the course of a day to rotate each of the plurality of solar cell array modules to track an elevation of the sun, and to rotate the longitudinal support about the first axis in a second direction after an end of the day;
the modules being pivotably coupled to the longitudinal supports for each to rotate along an axis substantially orthogonal to the first axis to track the azimuth position of the sun during the course of the day.

10. The terrestrial solar tracking photovoltaic array of claim 9, further comprising a first adapter that connects the slew speed reducer to the first longitudinal support and a second adapter that connects the slew speed reducer to the second longitudinal support, each of the adapters positioned between the inner end of the respective longitudinal support and the slew speed reducer.

11. The terrestrial solar tracking photovoltaic array of claim 10, wherein each adapter includes a first flange that connects against one of the first and second portions of the slew speed reducer, a second flange that connects to the inner end of the respective longitudinal support, and an intermediate section that extends between the first and second flanges.

12. The terrestrial solar tracking photovoltaic array of claim 9, wherein the first portion of the slew speed reducer includes an outer annular gear with teeth along an exterior surface and the second portion includes an inner annular member positioned within a central opening of the outer annular gear, the outer annular gear being connected to the one vertical support and the inner annular member being connected to the first and second longitudinal supports, the inner annular member being rotatable relative to the outer annular gear.

13. The terrestrial solar tracking photovoltaic array of claim 12, wherein the gear of the slew speed reducer includes a worm with a helical thread that engages with the teeth on the outer annular gear, the worm being connected to the inner annular member with the worm and the inner annular member being rotatable about the outer annular gear.

14. The terrestrial solar tracking photovoltaic array of claim 9, further including a balancing mechanism connected to one of the longitudinal supports and being configured to apply a force to rotationally urge the longitudinal support in the second direction.

15. The terrestrial solar tracking photovoltaic array of claim 9, further comprising a bracket connected to the one vertical support and to the first portion of the slew speed reducer to prevent the first portion from rotating with the second portion during rotation of the longitudinal supports.

16. A terrestrial solar tracking photovoltaic array comprising:
first and second longitudinal supports extending over the surface of the earth substantially in a north-south direction, the longitudinal supports each including opposing inner and outer ends;
a plurality of solar cell array modules connected to and spaced apart along the longitudinal supports, each of the solar cell modules comprising a support and a plurality of concentrating lenses positioned over respective optical receivers, each receiver comprising a III-V compound semiconductor solar cell;
a plurality of vertical supports spaced along the longitudinal supports to elevate the longitudinal supports over the surface of the earth, each of said vertical supports being spaced away from each of said solar cell array modules along the longitudinal supports;
a slew speed reducer positioned between the inner ends of the first and second longitudinal supports, the slew speed reducer including:
an outer ring with exterior teeth and connected to one of the plurality of vertical supports;
an inner ring positioned within the outer ring and journaled to rotate relative to the outer ring; and
a gear that mates with the exterior teeth of the outer ring and is connected to the inner ring;
a first adapter extending between and connected to the inner ring and the inner end of the first longitudinal support;
a second adapter extending between and connected to the inner ring and the inner end of the second longitudinal support;
the slew speed reducer configured to move the gear along the exterior teeth of the outer ring thereby rotating the inner ring, the first and second adapters, and the first and second longitudinal supports about a longitudinal axis to rotate each of the plurality of solar cell array modules to track an elevation of the sun.

17. The terrestrial solar tracking photovoltaic array of claim 16, further comprising a string of linkages spaced apart from the longitudinal supports, the string of linkages being movable along the longitudinal support to rotate each of the plurality of solar cell modules to track the azimuth of the sun during the course of the day.

18. A method of tracking the sun with a plurality of solar cell array modules that each include a plurality of concentrating lenses positioned over respective optical receivers with each receiver comprising a III-V compound semiconductor solar cell, the method comprising:
spacing the plurality of solar cell array modules along a longitudinal support, the longitudinal support including first and second discrete sections placed in an end-to-end orientation;
positioning a slew speed reducer between the two discrete sections of the longitudinal support and connecting the slew speed reducer to each of the first and second discrete sections;
activating the slew speed reducer and applying equal amounts of torque to each of first and second discrete sections and rotating the first and second discrete sections to move each of the plurality of solar cell array modules to track the sun during the course of a day; and
rotating each of the plurality of solar cell array modules about second axes to track the azimuth of the sun during the course of the day.

19. The method of claim 18, wherein activating the slew speed reducer includes engaging teeth on a worm with teeth on an exterior of an outer annular gear and moving the worm around a periphery of the outer annular gear, the outer annular gear being fixedly attached to a support to prevent rotation during activation of the slew speed reducer.

20. The method of claim 18, further comprising activating the slew speed reducer in a second direction at an end of the day and rotating the first and second discrete sections in an opposite direction to return the plurality of solar cell modules to a starting position.
